(19) United States
(12) Patent Application Publication
(10) Pub. No.: US 2018/0240775 A1
(43) Pub. Date: Aug. 23, 2018

(54) ELECTRONIC DEVICE AND METHOD FOR MANUFACTURING ELECTRONIC DEVICE

(71) Applicant: FUJITSU COMPONENT LIMITED, Tokyo (JP)

(72) Inventors: Rie Tsudome, Tokyo (JP); Osamu Daikuhara, Tokyo (JP)

(21) Appl. No.: 15/888,199

(22) Filed: Feb. 5, 2018

(30) Foreign Application Priority Data
Feb. 21, 2017 (JP) 2017-029990

(51) Int. Cl. H01L 23/00; H01L 33/62; H01L 33/54; H01L 31/02; H01L 31/0203

(52) U.S. Cl. CPC H01L 24/92; H01L 2924/15151; H01L 33/54; H01L 31/02002; H01L 31/0203; H01L 24/16; H01L 24/32; H01L 24/73; H01L 24/81; H01L 24/83; H01L 2224/16225; H01L 2224/32225; H01L 2224/17179; H01L 2224/73203; H01L 2224/26175; H01L 2224/92225; H01L 2224/81192; H01L 2224/81194; H01L 2224/83007; H01L 2224/8388; H01L 2924/182; H01L 33/62

(57) ABSTRACT

An electronic device includes a substrate, an electronic element mounted on the substrate, bumps that electrically connect the substrate to the electronic element, dummy bumps that are formed on the substrate to surround the electronic element, and a side fill that is formed around the electronic element and is in contact with the dummy bumps.

### CROSS-REFERENCE TO RELATED APPLICATION

The present application is based upon and claims the benefit of priority of Japanese Patent Application No. 2017-029990, filed on Feb. 21, 2017, the entire contents of which are incorporated herein by reference.

### BACKGROUND OF THE INVENTION

### 1. Field of the Invention

An aspect of this disclosure relates to an electronic device and a method for manufacturing the electronic device.

### 2. Description of the Related Art

An electronic device including a light-emitting element and a light-receiving element is used in the field of optical communication. Such an electronic device is called an optical module and is used for high-speed optical communication performed by, for example, supercomputers and high-end servers using high-speed interfaces.

In manufacturing such an electronic device, bumps are formed on a substrate, an electronic component is connected to the bumps by flip-chip bonding, and then a side fill is formed around the bumps (see, for example, Japanese Laid-Open Patent Publication No. 2013-102167).

In the manufacturing process described above, the side fill is formed by applying and curing a side fill resin after the flip chip bonding. A resin with a comparatively high viscosity of about 600 MP·sec is used as the side fill resin. However, when a large amount of side fill resin is applied and cured, the side fill resin may spread more than necessary and cover, for example, electrode terminals formed on a flexible substrate, a light emitter of a light-emitting element, and/or a light receiver of a light-receiving element. As a result, device characteristics may be degraded. Also, because a side fill resin with a high viscosity does not readily adhere to a flexible substrate, the application of the side fill resin requires much time, which results in increased manufacturing costs.

Accordingly, there is a demand for an electronic device and a method for manufacturing the electronic device that make it possible to easily apply a side fill resin to a substrate and form a side fill in a desired area with low costs.

### SUMMARY OF THE INVENTION

In an aspect of this disclosure, there is provided an electronic device including a substrate, an electronic element mounted on the substrate, bumps that electrically connect the substrate to the electronic element, dummy bumps that are formed on the substrate to surround the electronic element, and a side fill that is formed around the electronic element and is in contact with the dummy bumps.

### BRIEF DESCRIPTION OF THE DRAWINGS

FIG. 1 is a drawing illustrating an electronic device;

FIGS. 2A and 2B are drawings illustrating an electronic device according to a first embodiment;

FIGS. 3A through 3C are drawings illustrating a method for manufacturing the electronic device according to the first embodiment;

FIGS. 4A and 4B are drawings illustrating an electronic device according to a variation of the first embodiment;

FIG. 5 is a drawing illustrating an electronic device according to a variation of the first embodiment;

FIGS. 6A and 6B are drawings illustrating an electronic device according to a variation of the first embodiment;

FIGS. 7A and 7B are drawings illustrating an electronic device according to a variation of the first embodiment;

FIGS. 8A and 8B are drawings illustrating an electronic device according to a variation of the first embodiment;

FIGS. 9A and 9B are drawings illustrating an electronic device according to a variation of the first embodiment;

FIGS. 10A and 10B are drawings illustrating an electronic device according to a second embodiment;

FIGS. 11A and 11B are drawings illustrating an electronic device according to a third embodiment;

FIG. 12 is a drawing illustrating bumps of the electronic device according to the third embodiment;

FIGS. 13A and 13B are drawings illustrating an electronic device according to a fourth embodiment;

FIGS. 14A through 14C are drawings illustrating a method for manufacturing an electronic device including large dummy bumps;

FIG. 15 is a drawing illustrating a method for manufacturing an electronic device including large dummy bumps;

FIGS. 16A through 16C are drawings illustrating a method for manufacturing an electronic device according to a fifth embodiment; and

FIGS. 17A and 17B are drawings illustrating a method for manufacturing the electronic device according to the fifth embodiment.

### DESCRIPTION OF EMBODIMENTS

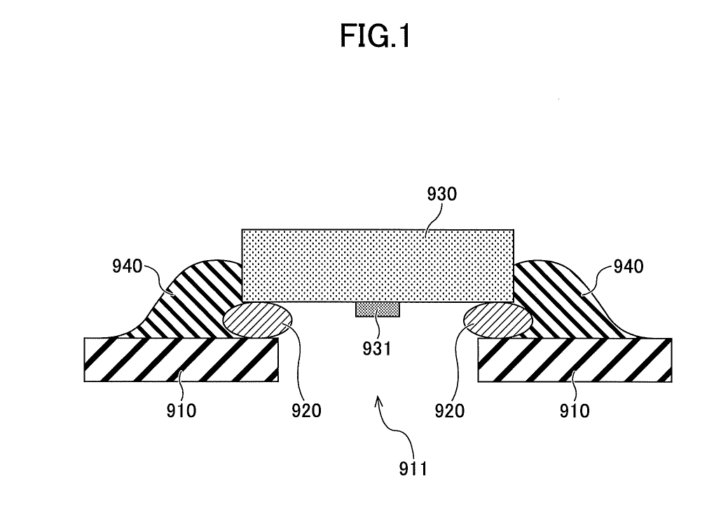

A method for mounting an electronic element such as a light-emitting element or a light-receiving element on a flexible substrate to manufacture an electronic device is described with reference to FIG. 1. In the example of FIG. 1, bumps 920 are formed on a flexible substrate (hereinafter “substrate”) 910, a light-emitting element 930 is connected to the bumps 920 by flip-chip bonding, and a side fill 940 is formed by applying a side fill resin to an area surrounding the light-emitting element 930 and curing the applied side fill resin. The side fill resin is a thermosetting resin, and heat is applied to cure the side fill resin. When heated, the viscosity of the side fill resin first decreases; and when further heated, the side fill resin is cured. The side fill resin with the decreased viscosity tends to spread beyond a desired area. As a result, the side fill resin may cover electrode terminals formed on the substrate 910 and a light emitter 931 of the light-emitting element 930. If the electrode terminals of the substrate 910 are covered by the side fill resin, the electrode terminals cannot be electrically connected to other components. Also, because the side fill resin is colored in, for example, black, if the light emitter 931 is covered by the side fill resin, light emitted from the light emitter 931 is blocked by the side fill resin.

Further, because the side fill resin has a high viscosity, a blank space may be left in the area to which the side fill resin needs to be applied. When a gap is formed in the side fill 940 due to the blank space, dust may pass through the gap in the side fill 940 and enter an opening 911 of the substrate 910 where the light-emitting element 930 is located. When dust enters the opening 911 and adheres to the light emitter 931, light emitted from the light emitter 931 is absorbed or scattered by the, dust. As a result, device characteristics are degraded and the reliability of the electronic device is reduced.

Embodiments of the present invention are described below with reference to the accompanying drawings. Throughout the drawings, the same reference number is assigned to the same component, and repeated descriptions of the same component are omitted.

### First Embodiment

### <Electronic Device>

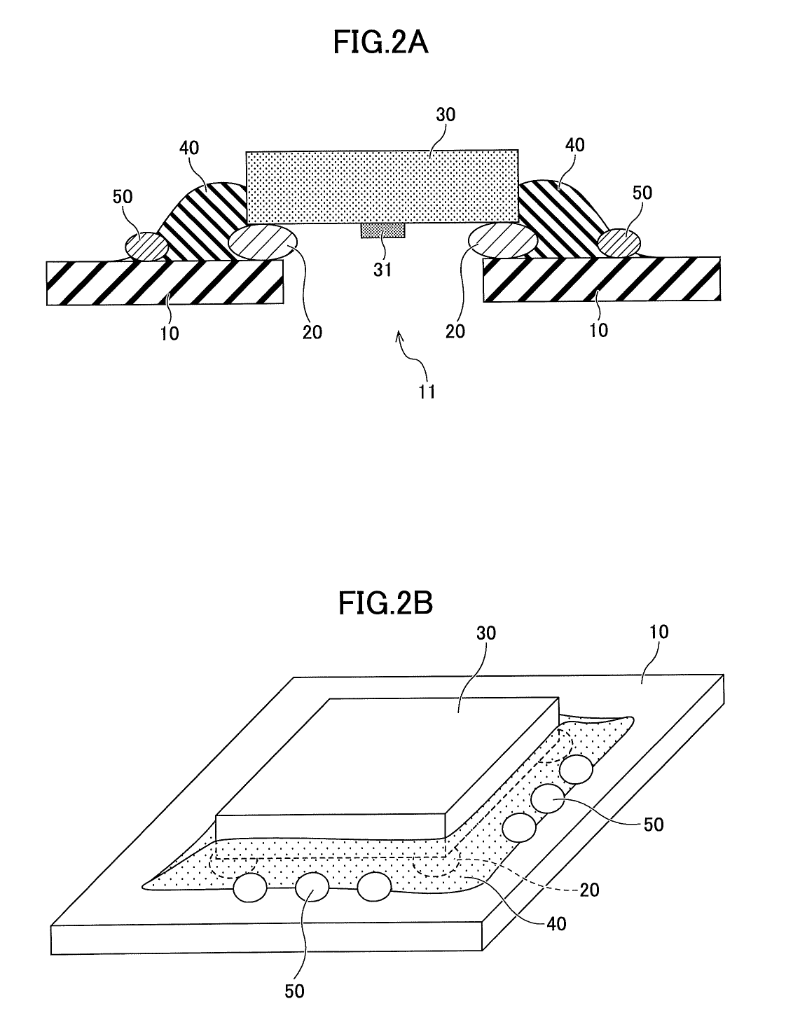

An electronic device according to a first embodiment is described below. FIG. 2A is a cross-sectional view and FIG. 2B is a perspective view of the electronic device according to the first embodiment.

As illustrated in FIGS. 2A and 2B, the electronic device includes a substrate 10, a light-emitting element 30, bumps 20 for connecting electrode terminals (not shown) of the substrate 10 to electrode terminals (not shown) of the light-emitting element 30, and dummy bumps 50 that are provided separately from the bumps 20 and formed in an outer area surrounding the bumps 20. An opening 11 is formed in the substrate 10, and the light-emitting element 30 is disposed such that a light emitter 31 faces the opening 11. In the descriptions below, a light-emitting element including a light emitter is used as an example of the electronic element. However, the electronic element may instead be a light-receiving element including a light receiver or any other type of electronic element including an electronic circuit.

A side fill 40 is formed by curing a side fill resin applied to the substrate 10. The dummy bumps 50 formed in the outer area surrounding the bumps 20 prevent the applied side fill resin from spreading outside of the dummy bumps 50. The side fill resin may be a resin material obtained, for example, by mixing a carbon filler in an epoxy resin and may have a black color. The bumps 20 and the dummy bumps 50 may be formed of the same metal material such as gold, copper, or solder.

Thus, providing dummy bumps outside an area to which a side fill resin is applied makes it possible to prevent the side fill resin from flowing outside of the dummy bumps.

According to the present embodiment, the side fill resin is applied to an area between the bumps 20 and the dummy bumps 50 formed around the bumps 20 such that the side fill resin contacts the dummy bumps 50. With this method, the applied side fill resin spreads due to surface tension to areas between the dummy bumps 50 and between the bumps 20 and the dummy bumps 50 without leaving a blank space. Forming the side fill 40 by curing the side fill resin spread without leaving a space makes it possible to prevent formation of a gap in the side fill 40. This in turn makes it possible to prevent dust from entering the opening 11 of the substrate 10 from outside of the side fill 40 and improve the reliability of the electronic device. This effect may be referred to as a dust preventing effect. Other embodiments described below can also achieve a similar dust preventing effect.

### <Method for Manufacturing Electronic Device>

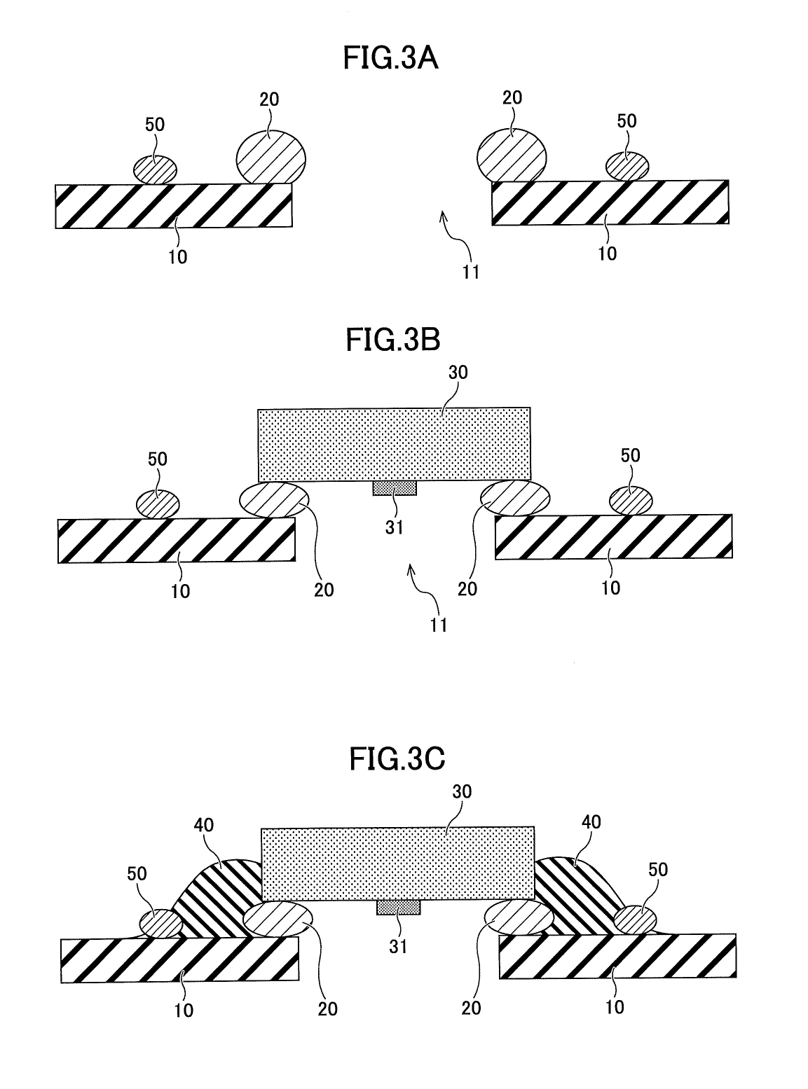

Next, a method for manufacturing an electronic device according to the first embodiment is described with reference to FIGS. 3A through 3C.

First, as illustrated in FIG. 3A, the bumps 20 are formed on the electrode terminals of the substrate 10, and the dummy bumps 50 are formed around the bumps 20 to surround the light-emitting element 30 to be mounted on the substrate 10. The bumps 20 and the dummy bumps 50 are formed of gold. For example, the bumps 20 and the dummy bumps 50 may be implemented by balls formed in wire bonding.

The bumps 20 have a diameter of about 70 μm, and the dummy bumps 50 have a diameter of about 40 μm. The dummy bumps 50 are not used for electric connection and therefore may be smaller than the bumps 20. The opening 11 is formed in the substrate 10 at a position corresponding to the light emitter 31, and electrode terminals (not shown) to be electrically connected to the light-emitting element 30 are formed around the opening 11. The bumps 20 are formed on the electrode terminals formed around the opening 11.

Next, as illustrated in FIG. 3B, the electrode terminals of the light-emitting element 30 are connected to the bumps 20 by flip-chip bonding. As a result, the electrode terminals of the substrate 10 are connected via the bumps 20 to the electrode terminals of the light-emitting element 30.

Next, as illustrated in FIG. 3C, a side fill resin is applied to an area between the bumps 20 and the dummy bumps 50 around the light-emitting element 30 such that the side fill resin contacts the dummy bumps 50, and the side fill resin is thermally cured to form the side fill 40. Although the viscosity of the side fill resin is comparatively high, the side fill resin can better adhere to an uneven surface formed by the bumps 20 and the dummy bumps 50 than to a flat surface of the substrate 10. Thus, forming the dummy bumps 50 makes it easier to apply the side fill resin and improves the manufacturing efficiency. When the side fill resin is thermally cured, the viscosity of the side fill resin first decreases. However, because the dummy bumps 50 block the flow of the side fill resin and prevent the side fill resin from spreading outside of the dummy bumps 50, electrode terminals of the substrate 10 other than those of the light-emitting element 30 are not covered by the side fill 40.

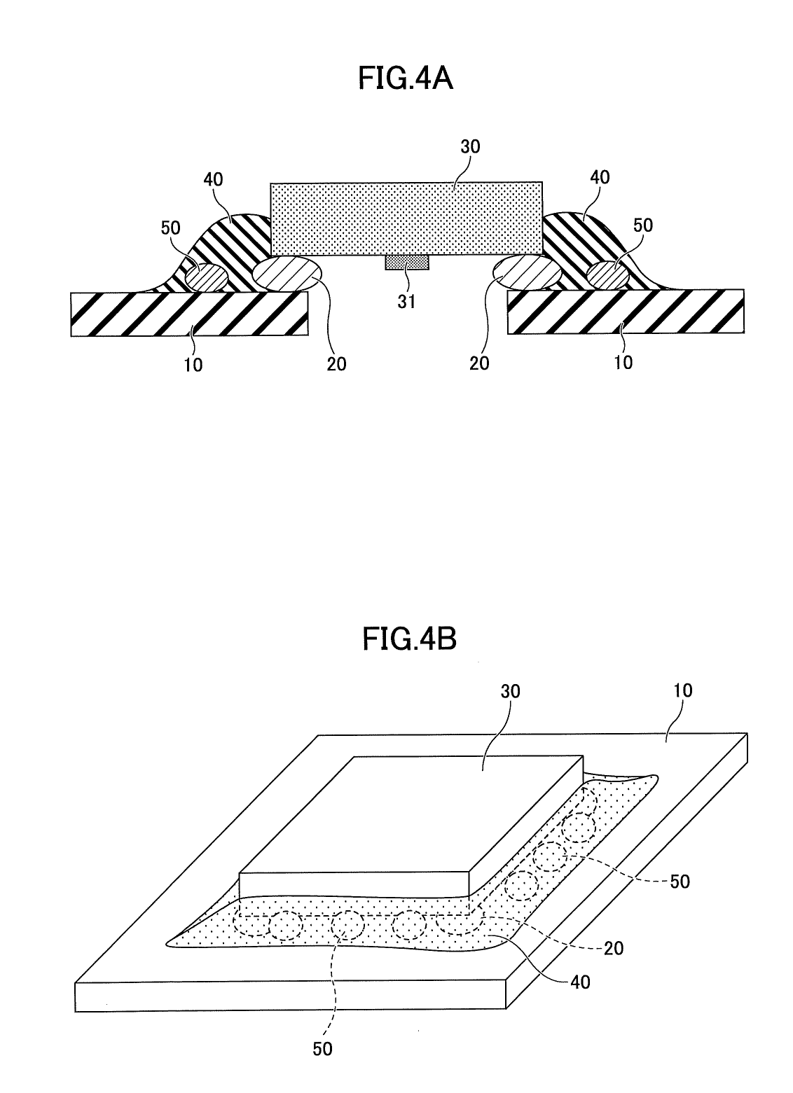

FIG. 4A is a cross-sectional view and FIG. 4B is a perspective view of an electronic device according to a variation of the first embodiment. In this variation, as illustrated in FIGS. 4A and 4B, the dummy bumps 50 are formed inside of an area to which the side fill resin is applied such that the dummy bumps 50 are covered by the side fill 40 Also in this case, because the side fill resin can easily adhere to an uneven surface formed by the bumps 20 and the dummy bumps 50, the side fill resin can be easily applied to the substrate 10. This configuration also prevents the side fill resin applied to an area outside the dummy bumps 50 from flowing into an area inside of the dummy bumps 50.

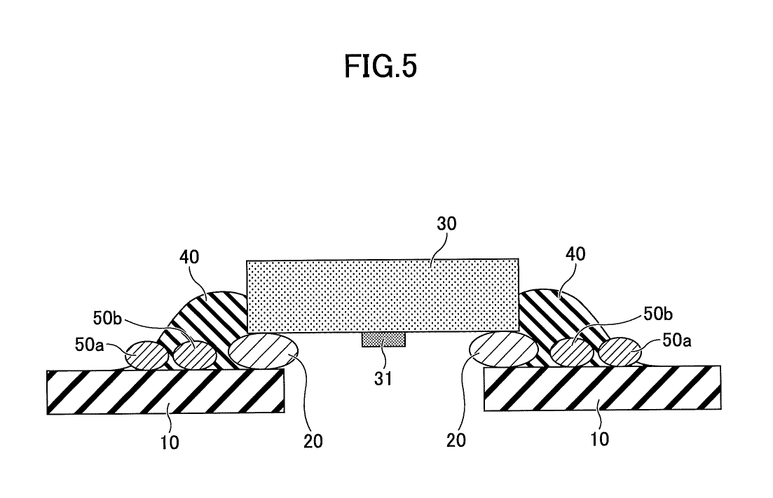

Also, as illustrated in FIG. 5, both of dummy bumps 50a (which correspond to the dummy bumps 50 in FIGS. 2A and 2B) and dummy bumps 50b (which correspond to the dummy bumps 50 in FIGS. 4A and 4B) may be formed on the substrate 10.

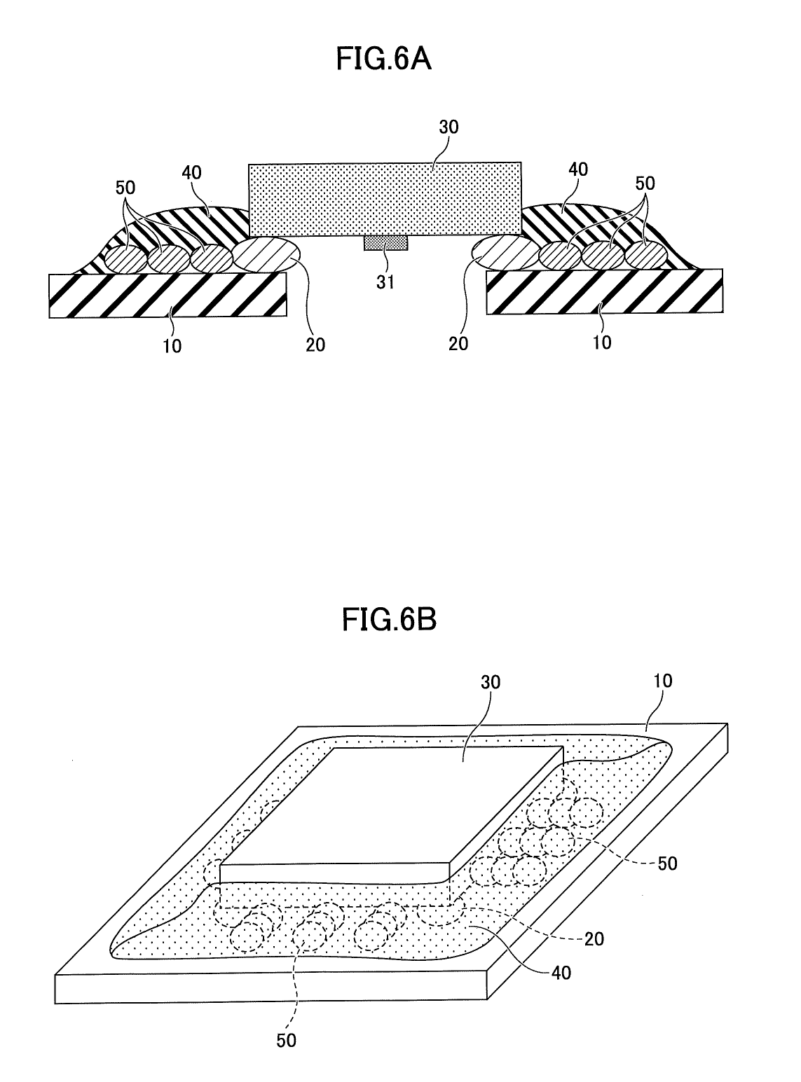

FIG. 6A is a cross-sectional view and FIG. 6B is a perspective view of an electronic device according to another variation of the first embodiment. In this variation, the number of dummy bumps 50 is increased. In FIGS. 6A and 6B, multiple rows of dummy bumps 50 are formed on the substrate 10. The dummy bumps 50 in each row are arranged in a direction away from the light-emitting element 30. Increasing the number of dummy bumps 50 results in increasing the number of gaps between the dummy bumps 50 and increasing the amount of side fill resin that enters the gaps. This in turn makes it possible to reduce the amount of side fill resin that spreads outside of the dummy bumps 50.

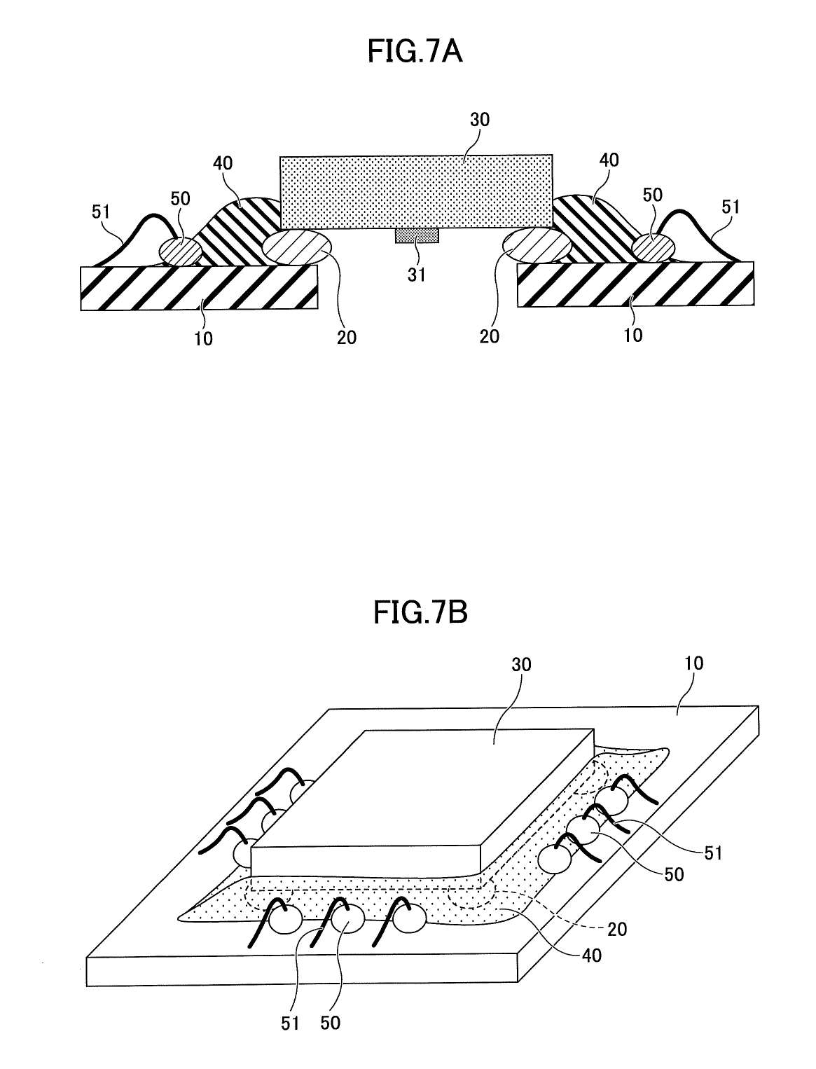

FIG. 7A is a cross-sectional view and FIG. 7B is a perspective view of an electronic device according to another variation of the first embodiment. In FIGS. 7A and 7B, the dummy bumps 50 are implemented by balls for wire bonding, and bonding wires 51 are connected to the dummy bumps 50. The bonding wires 51 may be located on the outer side of the dummy bumps 50 as illustrated in FIGS. 7A and 7B.

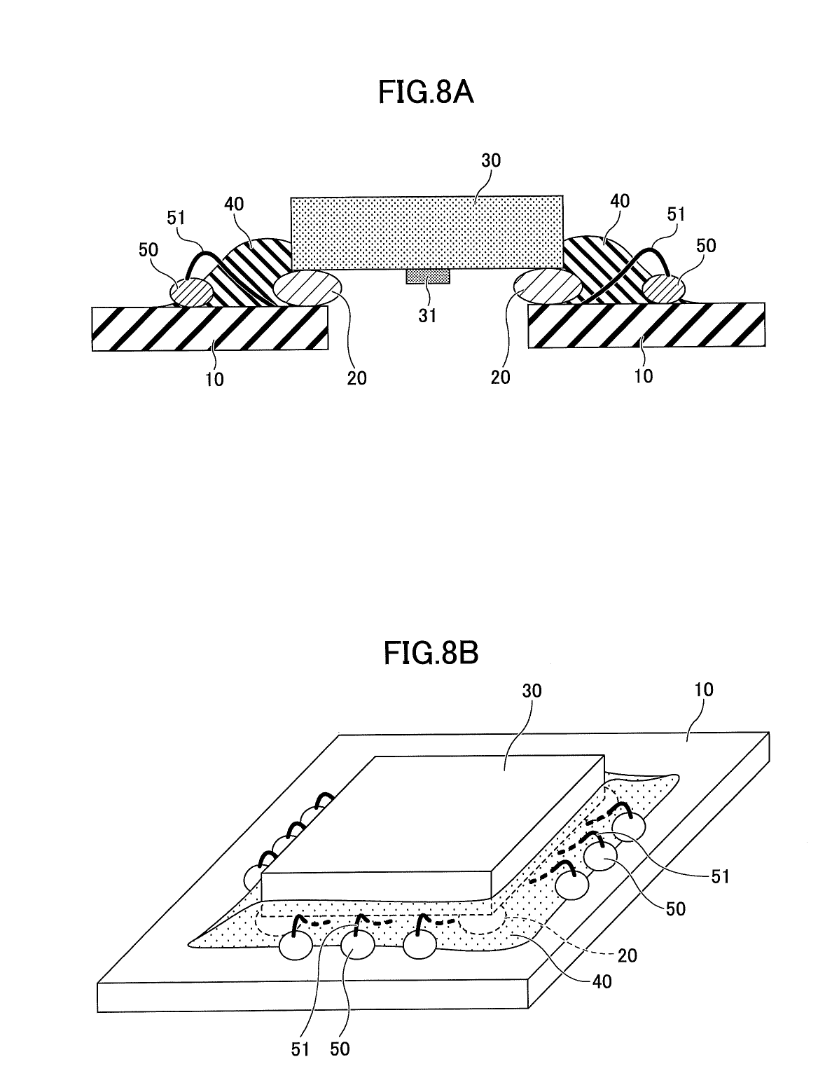

FIG. 8A is a cross-sectional view and FIG. 8B is a perspective view of an electronic device according to another variation of the first embodiment. As illustrated in FIGS. 8A and 8B, the bonding wires 51 may be located on the inner side of the dummy bumps 50. Forming the bonding wires 51 can further improve the efficiency in forming the side fill 40, and makes it possible to prevent formation of a blank space to which no side fill resin is applied.

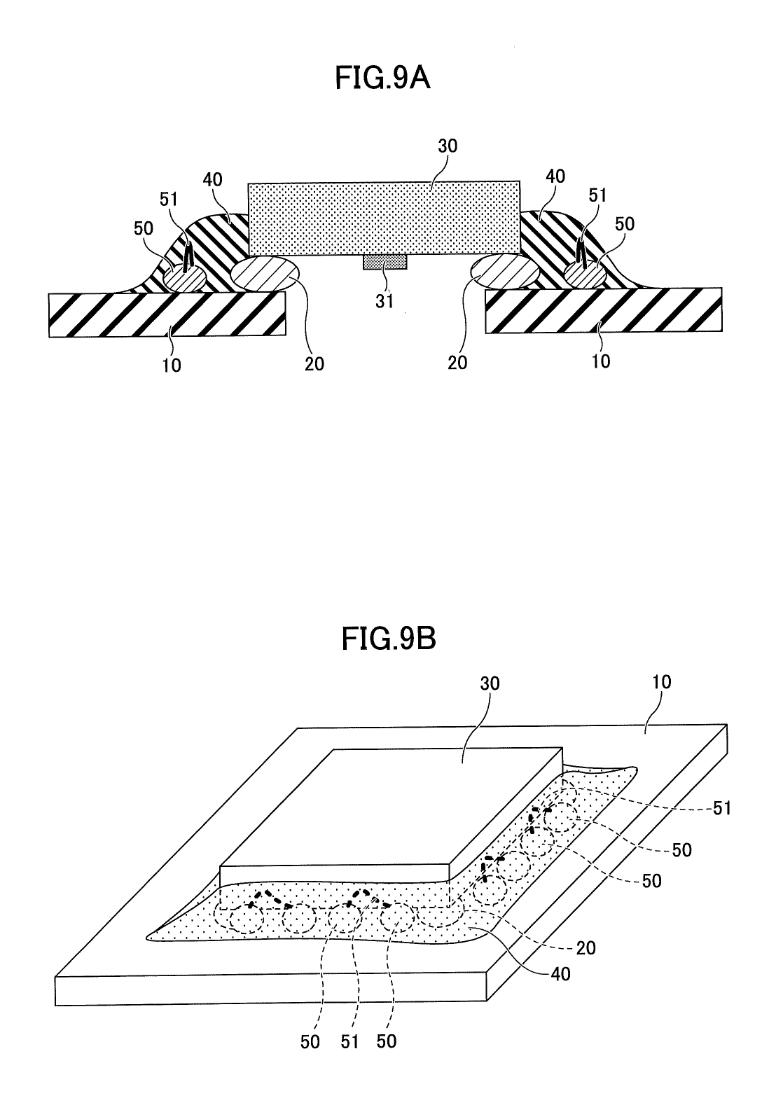

Also, as illustrated in FIGS. 9A and 9B, each pair of adjacent dummy bumps 50 may be connected by a bonding wire 51. This configuration is called Ball Stich on Ball (BSOB). In the BSOB configuration, each end of the bonding wire 51 is connected to a dummy bump 50. FIG. 9A is a cross-sectional view and FIG. 9B is a perspective view of the electronic device with the BSOB configuration.

### Second Embodiment

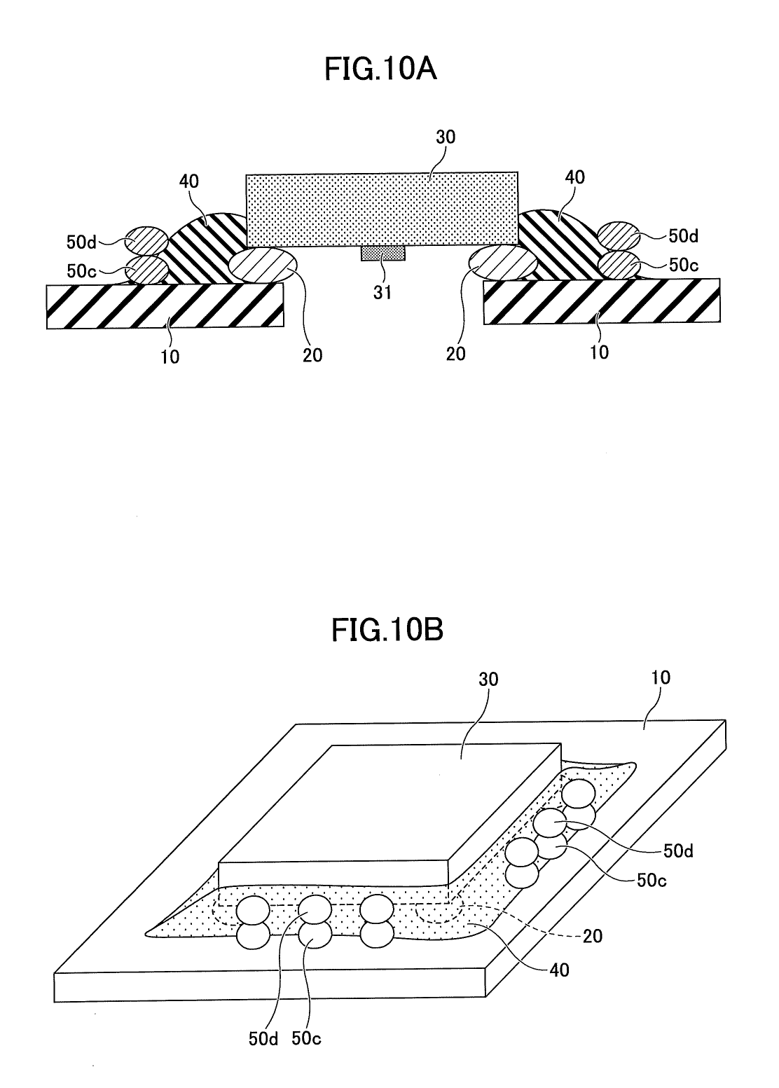

Next, a second embodiment is described. FIG. 10A is a cross-sectional view and FIG. 10B is a perspective view of an electronic device according to the second embodiment. In the second embodiment, as illustrated in FIGS. 10A and 10B, multiple dummy bumps are stacked on top of another. In the example of FIGS. 10A and 10B, a dummy bump 50c is formed on the substrate 10 and a dummy bump 50d is formed on the dummy bump 50c, and multiple stacks of the dummy bump 50c and the dummy bump 50d are formed.

Stacking dummy bumps makes it possible to increase the height of dummy bumps and thereby makes it possible to prevent the side fill resin from spreading over the dummy bumps.

Other configurations of the electronic device of the second embodiment are substantially the same as those described in the first embodiment.

### Third Embodiment

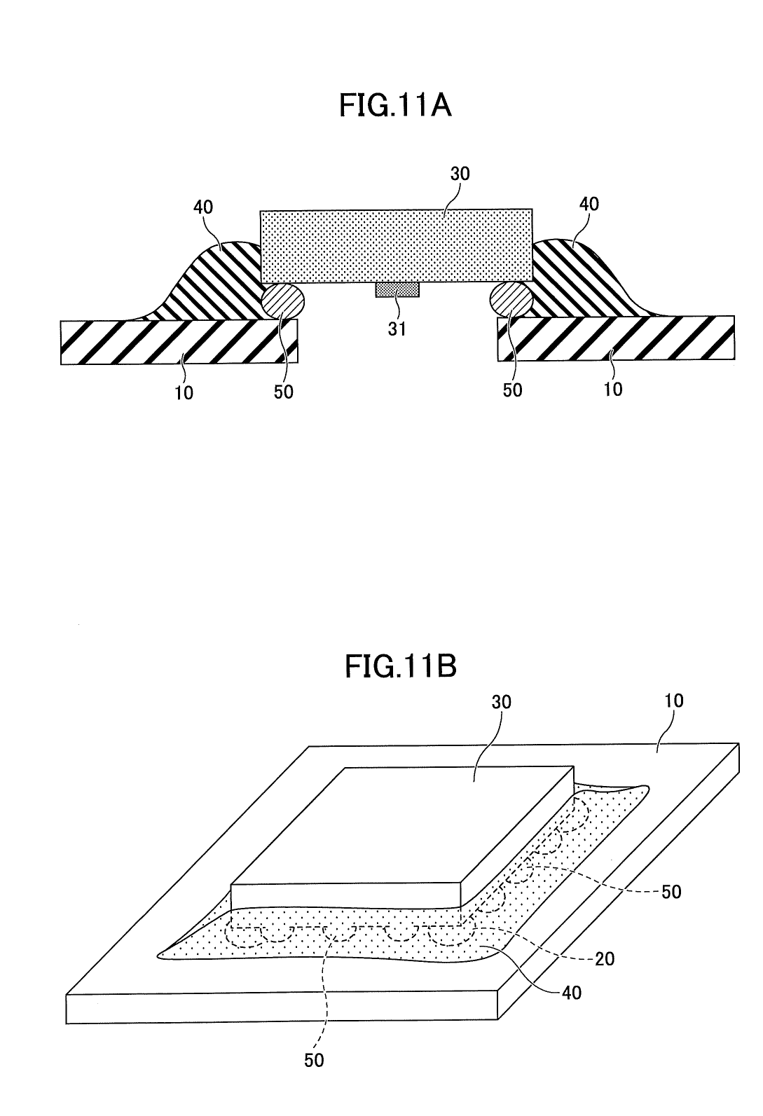

Next, a third embodiment is described. FIG. 11A is a cross-sectional view and FIG. 11B is a perspective view of an electronic device according to the third embodiment.

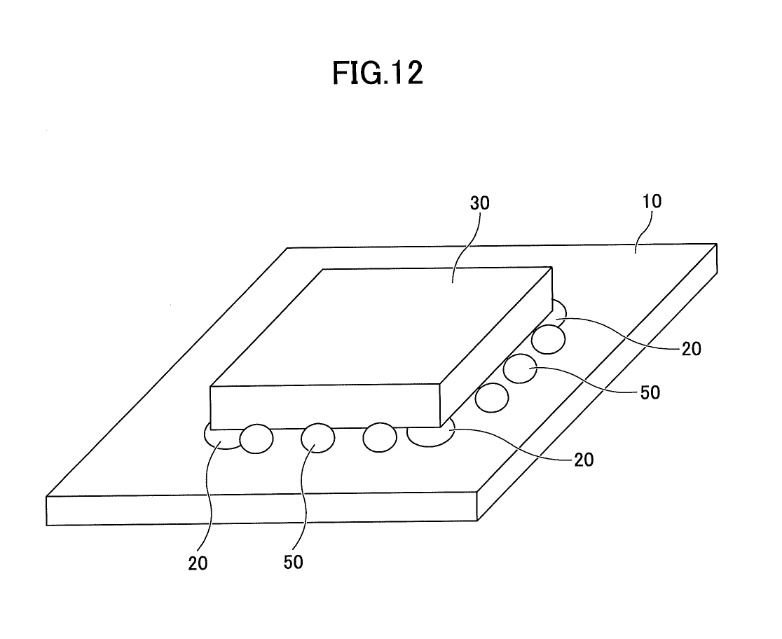

In the third embodiment, the dummy bumps 50 are formed between the bumps 20. If no dummy bump is provided in the electronic device, the applied side fill resin flows through gaps between the bumps 20 and may reach and cover the light emitter 31 of the light-emitting element 30. In the third embodiment, to prevent this problem, the dummy bumps 50 are formed between the bumps 20 as illustrated in FIG. 12. With this configuration, as illustrated in FIGS. 11A and 11B, the bumps 20 and the dummy bumps 50 prevent the side fill resin from flowing into an area below the light-emitting element 30. Thus, this configuration can prevent the light emitter 31 of the light-emitting element 30 from being covered by the side fill 40 and prevent degradation of the characteristics of the electronic device.

Other configurations of the electronic device of the third embodiment are substantially the same as those described in the first embodiment.

### Fourth Embodiment

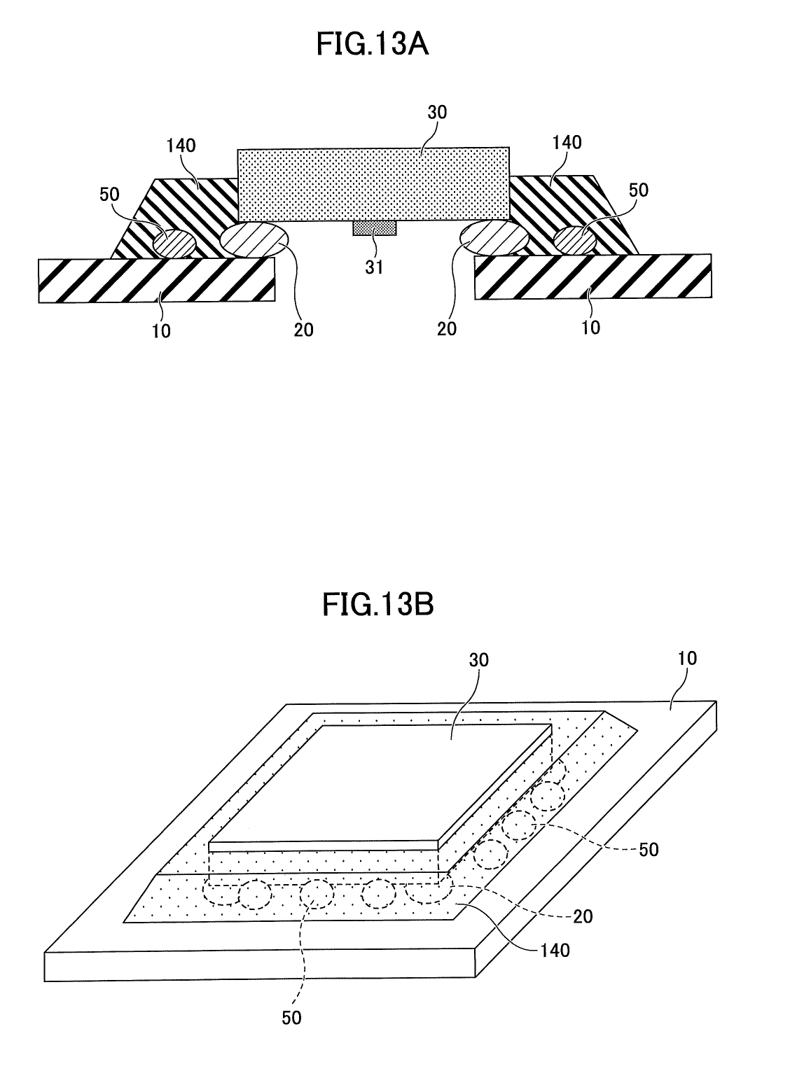

Next, a fourth embodiment is described. FIG. 13A is a cross-sectional view and FIG. 13B is a perspective view of an electronic device according to the fourth embodiment.

In the fourth embodiment, a side fill is formed using a thermosetting resin sheet. When the side fill resin is a liquid, it is difficult to control a dispenser to constantly supply a predetermined amount of the side fill resin, and the amount of the side fill resin supplied from the dispenser may sometimes exceed the predetermined amount. When the amount of the side fill resin exceeds the predetermined amount, the side fill resin spreads over a wider area.

In contrast, because a thermosetting resin sheet has a constant thickness, it is possible to provide a desired amount of thermosetting resin by cutting out a thermosetting resin sheet with a predetermined size. The cut-out thermosetting resin sheet is placed over the bumps 20 and the dummy bumps 50 and is thermally cured to form a side fill 140 as illustrated in FIGS. 13A and 13B. In the fourth embodiment, the amount of thermosetting resin for forming the side fill 140 is the same as long as the area of the thermosetting resin sheet is the same. Accordingly, the fourth embodiment makes it easier to control the amount of side fill resin and can prevent the side fill resin from spreading into an undesired area.

Other configurations of the electronic device of the fourth embodiment are substantially the same as those described in the first embodiment.

### Fifth Embodiment

Next, a fifth embodiment is described. In forming a side fill, larger dummy bumps may more effectively prevent the spread of an applied side fill resin and prevent dust. However, if an electronic device including large dummy bumps is manufactured according to a method similar to the manufacturing method of the first embodiment, problems as described below may occur.

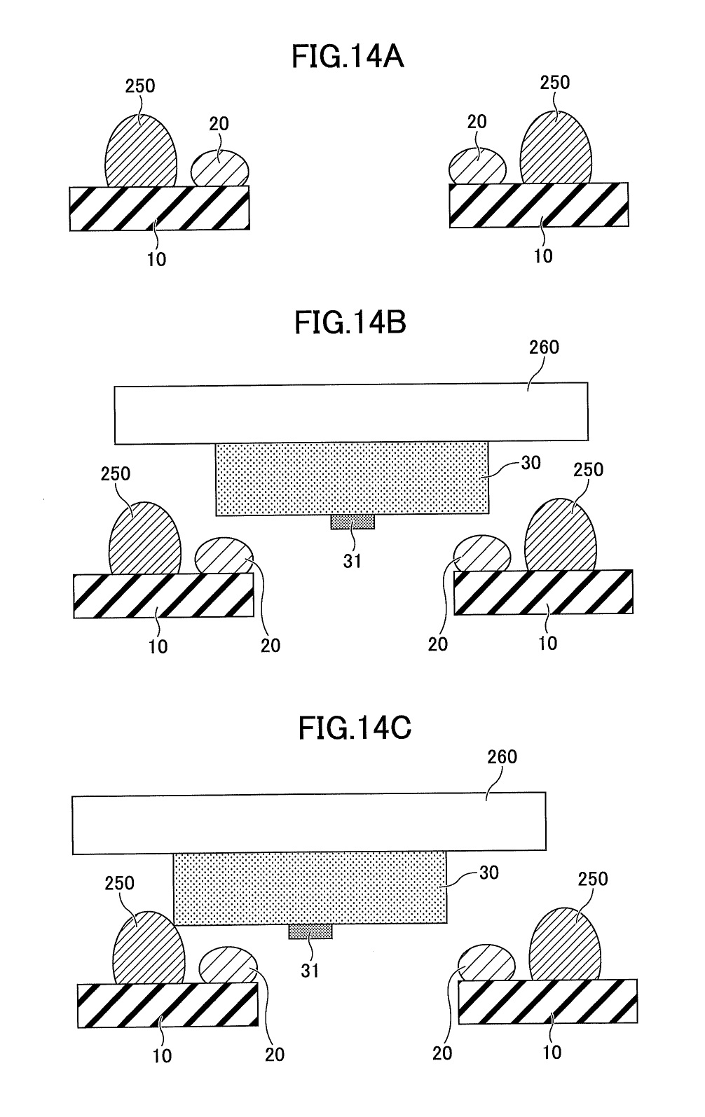

In FIG. 14A, bumps 20 are formed on the electrode terminals of the substrate 10, and large dummy bumps 250 are formed around the bumps 20. The bumps 20 and the dummy bumps 250 are formed of gold. The bumps 20 have a height of about 70 μm, and the dummy bumps 250 are larger than the bumps 20 and have a height of about 100 μm,

Next, as illustrated in FIG. 14B, the light-emitting element 30 is positioned using a jig 260. Here, in the next step where the electrode terminals of the light-emitting element 30 are connected to the bumps 20 by flip-chip bonding, if the light-emitting element 30 is misaligned even slightly as illustrated in FIG. 14C, the light-emitting element 30 may contact the dummy bumps 250 and may be damaged while being moved toward the bumps 20. Also, if the jig 260 contacts other components on the substrate 10, the light-emitting element 30 cannot be mounted on the bumps 20. To prevent these problems, an area that has a predetermined width and where no bump is formed may be defined outside of the bumps 20.

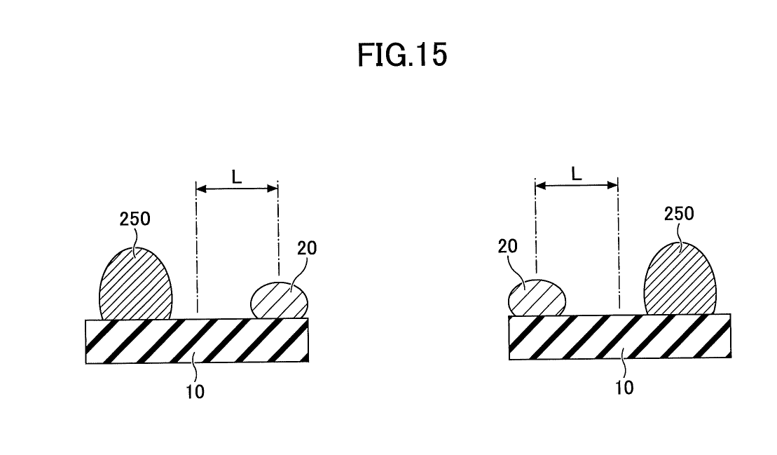

For example, as illustrated in FIG. 15, each dummy bump 250 may be formed in a position that is away from the center of the bump 20 by a predetermined distance L or more. However, this configuration increases the size of the electronic device and is therefore not preferable. To reduce the size of the electronic device, the dummy bumps 250 are preferably positioned as close as possible to the bumps 20.

To prevent the above problems and prevent an increase in the size of an electronic device, a manufacturing method as described below is used in the fifth embodiment.

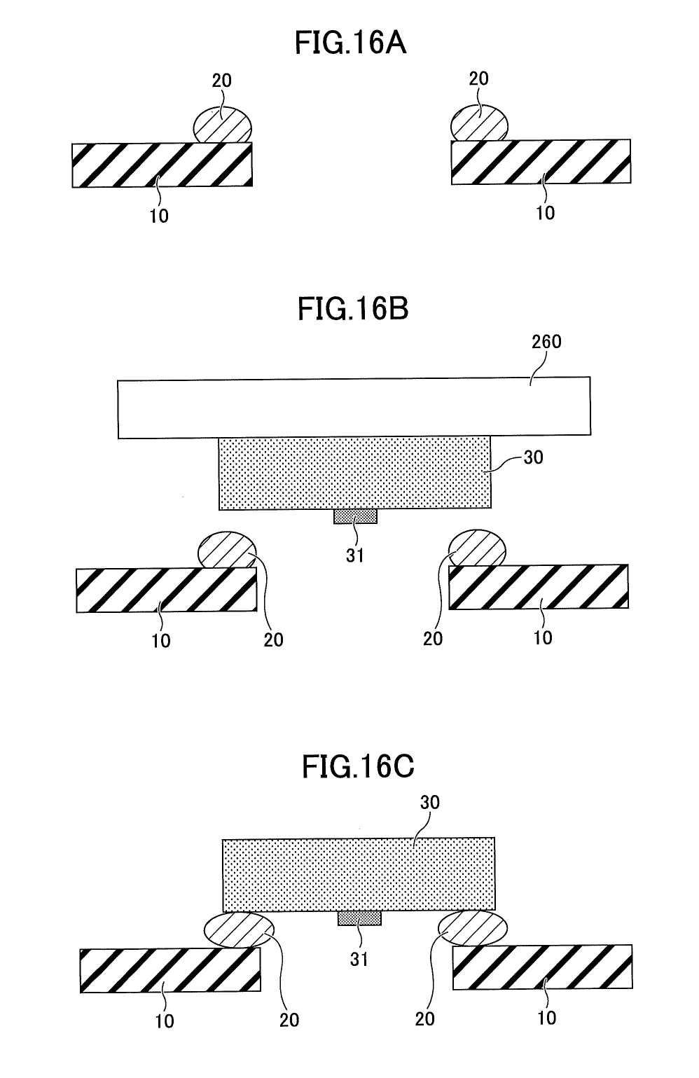

First, as illustrated in FIG. 16A, the bumps 20 are formed on the electrode terminals of the substrate 10.

Next, the light-emitting element 30 is positioned using the jig 260 as illustrated in FIG. 16B, and the electrode terminals of the light-emitting element 30 are connected to the bumps 20 by flip-chip bonding as illustrated in FIG. 16C. In this step, because the large dummy bumps 250 have not been formed yet, the light-emitting element 30 can be easily connected to the bumps 20 without damaging the light-emitting element 30.

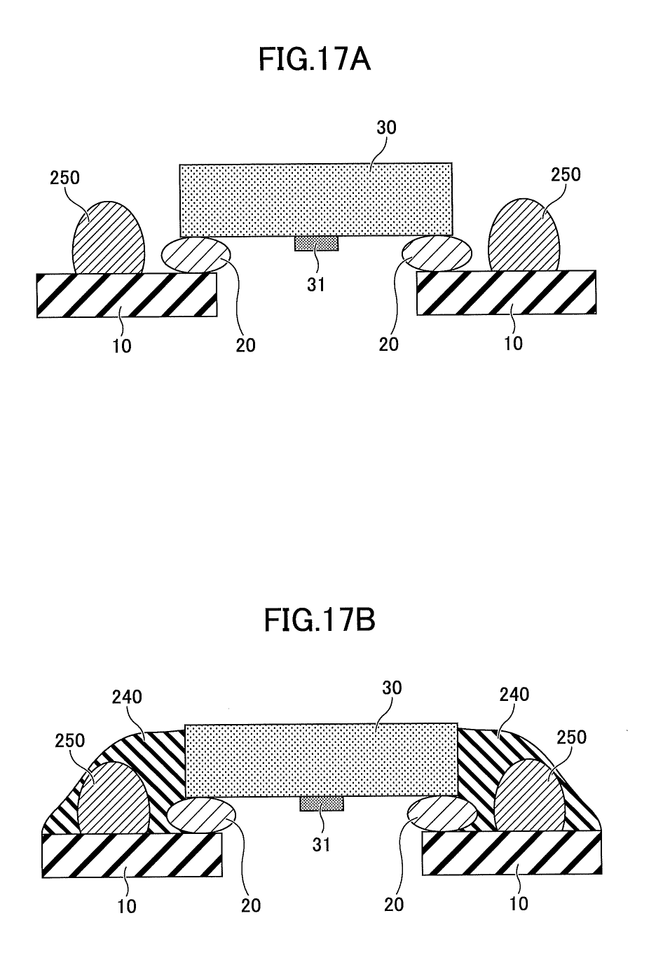

Next, as illustrated in FIG. 17A, the dummy bumps 250 are formed around the bumps 20 after mounting the light-emitting element 30. The dummy bumps 250 have a height of about 100 μm and are larger than the bumps 20 having a height of about 70 μm. Because the light-emitting element 30 has already been mounted on the substrate 10 when the dummy bumps 250 are formed, even if the distance between the bumps 20 and the dummy bumps 250 is short, the dummy bumps 250 do not contact the light-emitting element 30 and the jig 260 holding the light-emitting element 30.

Then, as illustrated in FIG. 17B, a side fill resin is applied to an area between the bumps 20 and the dummy bumps 250 around the light-emitting element 30, and is thermally cured to form a side fill 240. The side fill resin enters and stays in the area between the bumps 20 and the dummy bumps 250 and is cured. As a result, the area surrounding the light-emitting element 30 is covered by the cured side fill 240.

Thus, the fifth embodiment makes it possible to form the dummy bumps 250, which are larger than the bumps 20, in positions close to the bumps 20. This in turn makes it possible to prevent the side fill resin from spreading into an undesired area and to manufacture a dust-resistant electronic device without increasing the size of the electronic device.

Other configurations of the electronic device of the fifth embodiment are substantially the same as those described in the first embodiment.

An aspect of this disclosure provides an electronic device and a method for manufacturing the electronic device that make it possible to easily apply a side fill resin to a substrate and form a side fill in a desired area with low costs.

Electronic devices and methods for manufacturing the electronic devices according to embodiments of the present invention are described above. However, the present invention is not limited to the specifically disclosed embodiments, and variations and modifications may be made without departing from the scope of the present invention.

What is claimed is:

1. An electronic device, comprising:
a substrate;
an electronic element mounted on the substrate;
bumps that electrically connect the substrate to the electronic element;
dummy bumps that are formed on the substrate to surround the electronic element; and
a side fill that is formed around the electronic element and is in contact with the dummy bumps.

2. The electronic device as claimed in claim 1, wherein
the electronic element is a light-emitting element or a light-receiving element;
the substrate includes an opening that is formed in a position corresponding to a light emitter of the light-emitting element or a light receiver of the light-receiving element; and
the bumps are formed around the opening.

3. A method for manufacturing an electronic device, the method comprising:
forming bumps on a substrate;
connecting an electronic element via the bumps to the substrate;
after connecting the electronic element to the substrate, forming dummy bumps on the substrate;
applying a side fill resin onto the bumps and the dummy bumps; and
curing the side fill resin.
